(19) United States
(12) Patent Application Publication
(10) Pub. No.: US 2018/0260094 A1
(43) Pub. Date: Sep. 13, 2018

(54) ELECTRONIC DEVICE AND FUNCTION CONTROL METHOD THEREFOR

(71) Applicant: Samsung Electronics Co., Ltd., Gyeonggi-do (KR)

(72) Inventors: Sangeun KIM, Gyeonggi-do (KR); Kiyoung KWON, Gyeonggi-do (KR); Kyunghwan KIM, Gyeonggi-do (KR); Jihoon PARK, Gyeonggi-do (KR); Taeyoon AN, Gyeonggi-do (KR); Taewon UM, Seoul (KR); Inho OH, Gyeonggi-do (KR); Jaewoong CHOI, Seoul (KR)

(21) Appl. No.: 15/761,219

(22) PCT Filed: Sep. 7, 2016
(86) PCT No.: PCT/KR2016/009993

§ 371 Date: Mar. 19, 2018

(30) Foreign Application Priority Data
Sep. 18, 2015 (KR) 10-2015-0132288

(51) Int. Cl. G06F 3/0488; G06F 3/16; H05K 5/06; G06F 3/0484; G06F 3/0481

(52) U.S. Cl. CPC G06F 3/0488; G06F 3/16; G06F 3/0481; G06F 3/0484; H05K 5/06

(57) ABSTRACT

Disclosed in various examples are an electronic device comprising a rotary switch, and a function control method therefore, the electronic device comprising the rotary switch by which a user can select a waterproof function and a microphone function, and informing, through an icon and/or a sound, the user of whether the electronic device is in a waterproof mode or a microphone mode according to the operation of the rotary switch, such that the user can easily select the waterproof mode or the microphone mode.

### TECHNICAL FIELD

Embodiments disclosed herein relate to an electronic device having a rotatable element capable of selecting a waterproof function and a microphone function, and a method for controlling a function of the electronic device.

### BACKGROUND ART

Normally, a mobile terminal refers to a portable electronic device having a voice and video call function, an information input/output function, and a data storing function.

As functions of this mobile terminal are diversified, the mobile terminal is being implemented in the form of a multimedia device having complicated functions such as a digital camera, a music or video player, a game player, a broadcast receiver, and the like.

The multimedia device is being developed variously in order to realize such complicated functions in terms of hardware and software.

For example, a user interface environment for allowing a user to easily and conveniently search for or select a function is provided in the multimedia device.

Meanwhile, the mobile terminal needs to be designed in various forms to meet a variety of users' demands. In recent years, a wearable mobile terminal that can be worn on a user's body, for example, a watch-type terminal being wearable on the wrist has been launched.

### DISCLOSURE OF INVENTION

### Technical Problem

In the wearable mobile terminal such as a watch-type terminal, a voice input may be often used through a microphone as an input device.

On the other hand, the wearable mobile terminal requires in general a waterproof function for the input device because the user performs many activities while wearing the terminal.

However, when the microphone is used as the input device of the watch-type terminal, a path of the microphone should be connected to the outside of the terminal and thus may be weak in waterproofing. As a result, the waterproof performance of the watch-type terminal is lower than that of a normal watch, so that it may not be possible to play in water, swim, and dive.

Various embodiments disclosed herein provide a rotatable element capable of selecting the waterproof function and the microphone function, and may control the function thereof.

Various embodiments disclosed herein will be apparent to those skilled in the art without departing from the technical features of the present invention set forth in the appended claims.

### Solution to Problem

According to various embodiments of the present disclosure, an electronic device may comprise a switching element configured to close or open a microphone path so that a first function or a second function is performed; a sensor unit configured to detecting whether the microphone path is closed or opened; a touch screen configured to display whether the first function or the second function is performed; and a controller configured to perform the first function or the second function.

In addition, according to various embodiments of the present disclosure, a method for controlling a function of an electronic device may comprise at a controller, measuring an external noise delivered through a microphone path of the electronic device; at the controller, determining whether the measured noise is a predetermined level or less; at the controller, when the measured noise is equal to or smaller than the predetermined level, recognizing that the microphone path of the electronic device is closed; and at the controller, providing an identifying indication to a waterproof function icon through a display unit.

In addition, according to various embodiments of the present disclosure, a method for controlling a function of an electronic device may comprise at a controller, displaying, through a display unit, a state of performing a first function or a second function by the electronic device; at the controller, determining whether there is a rotation operation of a switching element; at the controller, detecting a completion of the rotation operation of the switching element; at the controller, when the completion of the rotation operation of the switching element is detected, recognizing that a microphone path of the electronic device is closed; and at the controller, providing an identifying indication to a first function icon through a display unit.

In addition, according to various embodiments of the present disclosure, a method for controlling a function of an electronic device may comprise at a controller, displaying, through a display unit, a state of performing a first function or a second function by the electronic device; at the controller, determining whether there is a touch input through a touch panel; at the controller, when there is the touch input, determining whether a first function icon or a second function icon is selected; and at the controller, when there is a signal of selecting the first function icon, closing a microphone path through a blocking member by rotating a switching element in one direction.

In addition, according to various embodiments of the present disclosure, a method for controlling a function of an electronic device may comprise at a controller, receiving a signal for performing a first function or a second function by closing or opening a microphone path through a switching element; at the controller, receiving a detection signal, from a sensor unit, indicating whether the microphone path is closed or opened in response to an operation of the switching element; and at the controller, displaying, through a touch screen, whether the first function or the second function is performed.

In addition, according to various embodiments of the present disclosure, a non-transitory computer-readable recording medium having, recorded thereon, a program for controlling functions of an electronic device, the functions comprising at a controller, displaying, through a display unit, a state of performing a first function or a second function by the electronic device; at the controller, determining whether there is a touch input through a touch panel; at the controller, when there is the touch input, determining whether a first function icon or a second function icon is selected; and at the controller, when there is a signal of selecting the first function icon, closing a microphone path through a blocking member by rotating a switching element in one direction.

### Advantageous Effects of Invention

According to various embodiments disclosed herein, an electronic device includes a rotatable element, such as a rotary switch, capable of selecting a waterproof function and a microphone function, and informs a user, through an icon and/or sound, about a waterproof mode or a microphone mode according to the operation of the rotary switch, so that the user can easily select the waterproof mode or the microphone mode.

In addition, according to various embodiments disclosed herein, a rotary switch capable of controlling a waterproof mode or a microphone mode is used to usually close a microphone path for the waterproof mode and, only when a microphone function is required, to physically open the microphone path. This can achieve a reliable waterproof performance of 3 atm or more, for example.

Furthermore, according to various embodiments disclosed herein, by touching a waterproof mode icon or a microphone mode icon displayed on a touch screen to operate a rotary switch through a controller or a rotary switch controller, it is possible to easily select a waterproof function or a microphone function.

### BRIEF DESCRIPTION OF DRAWINGS

FIG. 1 is a diagram illustrating a network environment including an electronic device according to various embodiments of the present disclosure.

FIG. 2 is a block diagram illustrating an internal configuration of an electronic device having a rotary switch according to an embodiment of the present disclosure.

FIG. 3 is a diagram illustrating an example of a waterproof function icon or a microphone function icon displayed on a display unit according to an embodiment of the present disclosure.

FIG. 4 is a flow diagram illustrating a method for controlling a function of an electronic device having a rotary switch through noise measurement of an external environment according to various embodiments of the present disclosure.

FIG. 5 is a flow diagram illustrating a method for controlling a function of an electronic device having a rotary switch through a magnet and a Hall IC sensor according to various embodiments of the present disclosure.

Parts (a) and (b) of FIG. 6 are diagrams illustrating configurations for implementing the method, shown in FIG. 5, for controlling a function of an electronic device through a magnet and a Hall IC sensor.

Parts (a) to (c) of FIG. 7 are diagrams illustrating an operating relationship between a rotary switch and a housing thereof.

FIG. 8 is a flow diagram illustrating a method for controlling a function of an electronic device having a rotary switch through a push button according to various embodiments of the present disclosure.

Parts (a) and (b) of FIG. 9 are diagrams illustrating configurations for implementing the method, shown in FIG. 8, for controlling a function of an electronic device through a push button.

FIG. 10 is a flow diagram illustrating a method for controlling a function of an electronic device having a rotary switch through a touch screen according to various embodiments of the present disclosure.

FIG. 11 is a block diagram of an electronic device according to various embodiments of the present disclosure.

### MODE FOR THE INVENTION

Hereinafter, various embodiments of the present disclosure are described with reference to the accompanying drawings. It should be understood that embodiments and terminology used therein are not intended to limit the disclosed technique to particular implementation, but various modifications, equivalents, and/or alternatives of the embodiments are included. In the description of the drawings, like reference numerals may be used for similar elements.

In this disclosure, the terms such as “comprise”, “include”, and “have” denote the presence of stated elements, components, operations, functions, features, and the like, but do not exclude the presence of or a possibility of addition of one or more other elements, components, operations, functions, features, and the like.

In this disclosure, the expressions “A or B”, “at least one of A and/or B”, and the like may include all possible combinations of items listed together. For example, “A or B”, “at least one of A and B”, or “at least one of A or B” may indicate all of (1) including at least one A, (2) including at least one B, and 3) including both of at least one A and at least one B.

The expressions including ordinal numbers, such as “first” and “second,” may indicate various elements. The above expressions do not limit the sequence or importance of the elements, and are used merely for the purpose to distinguish one element from the others. For example, a first electronic device and a second electronic device may indicate different electronic devices regardless of the sequence or importance thereof. For example, without departing from the scope of the present disclosure, a first element may be referred to as a second element, and similarly a second element may be also referred to as a first element.

When a certain element (e.g., first element) is referred to as being “connected” or “coupled” (operatively or communicatively) to another element (e.g., second element), it may mean that the first element is connected or coupled directly to the second element or indirectly through any other element (e.g., third element). On the other hand, when a certain element (e.g., first element) is referred to as being “directly connected” or “directly coupled” to another element (e.g., second element), it may be understood that there is no element (e.g., third element) therebetween.

The expression “configured to” may be interchangeably used with any other expressions “suitable for”, “having the ability to”, “designed to”, “adapted to”, “made to”, “being able to”, and “capable of”. The expression “device configured to” may mean that the device, together with other devices or components, “is able to”. For example, the phrase “processor configured to perform A, B and C” may mean a dedicated processor (e.g., embedded processor) for performing corresponding operations or a generic-purpose processor (e.g., central processing unit (CPU) or application processor (AP)) capable of performing corresponding operations by executing one or more software programs stored in a memory.

Terms used herein may be merely to describe a certain embodiment, and may not be intended to limit the scope of other embodiments. The singular expressions may include plural expressions unless the context clearly dictates otherwise. Terms used herein, including technical or scientific terms, may have the same meaning as commonly understood by those skilled in the art. Some terms defined in a normal dictionary may be interpreted as having the same or similar meaning as the contextual meanings in the related art. Certain terms are not to be construed as an ideal or overly formal sense unless expressly defined to the contrary herein. In some cases, the terms defined herein cannot be construed to exclude embodiments of the present disclosure.

In this disclosure, an electronic device may include at least one of a smart phone, a tablet PC, a mobile phone, a video phone, an e-book reader, a desktop PC, a laptop PC, a netbook computer, a workstation, a server, a personal digital assistant (PDA), a portable multimedia player (PMP), an MP3 player, a portable medical device, a digital camera, or a wearable device. This wearable device may include at least one of an accessory-type device (e.g., a watch, a ring, a bracelet, an anklet, a necklace, glasses, a contact lens, or a head-mounted device (HMD), a fabric- or cloth-type device (e.g., electronic cloth), a body-attached type device (e.g., a skin pad or tattoo), or a body-implemented type circuit.

In some embodiments, an electronic device may include at least one of a TV, a digital video disk (DVD) player, audio equipment, a refrigerator, an air conditioner, a vacuum cleaner, an oven, a microwave, a washing machine, an air cleaner, a set-top box, a home automation control panel, a security control panel, a media box (e.g., Samsung HomeSync™, Apple TV™, or Google TV™), a game console (e.g., Xbox™, PlayStation™), an electronic dictionary, an electronic key, a camcorder, or an electronic picture frame.

In some embodiments, an electronic device may include at least one of a medical device (e.g., portable medical measuring equipment (e.g., a blood sugar meter, a heart rate meter, a blood pressure meter, a clinical thermometer, etc.), a magnetic resonance angiography (MRA), a magnetic resonance imaging (MRI), a computed tomography (CT), an ultrasonography, etc.), a navigation device, a global navigation satellite system (GNSS), an event data recorder (EDR), a flight data recorder (FDR), a car infotainment device, electronic equipment for ship (e.g., a marine navigation system, a gyrocompass, etc.), avionics, security equipment, a car head unit, an industrial or home robot, a drone, an automated teller machine (ATM), a point of sales (POS), or a device for internet of things (IoT) (e.g., a bulb, a sensor, a sprinkler, a fire alarm, a thermostat, a streetlight, a toaster, athletic equipment, a hot-water tank, a heater, a boiler, etc.).

According to some embodiments, an electronic device may be include at least one of furniture, a part of a building/construction or car, an electronic board, an electronic signature receiving device, a projector, or various measuring instruments (e.g., a water meter, an electric meter, a gas meter, a wave meter, etc.). An electronic device disclosed herein may be one of the above-mentioned devices or any combination thereof. As well understood by those skilled in the art, the above-mentioned electronic devices are exemplary only and not to be considered as a limitation of this disclosure.

Now, an electronic device according to various embodiments of the present disclosure will be described with reference to the accompanying drawings. The term user may refer to a person using the electronic device, or a device (e.g., an artificial intelligence device) using the electronic device.

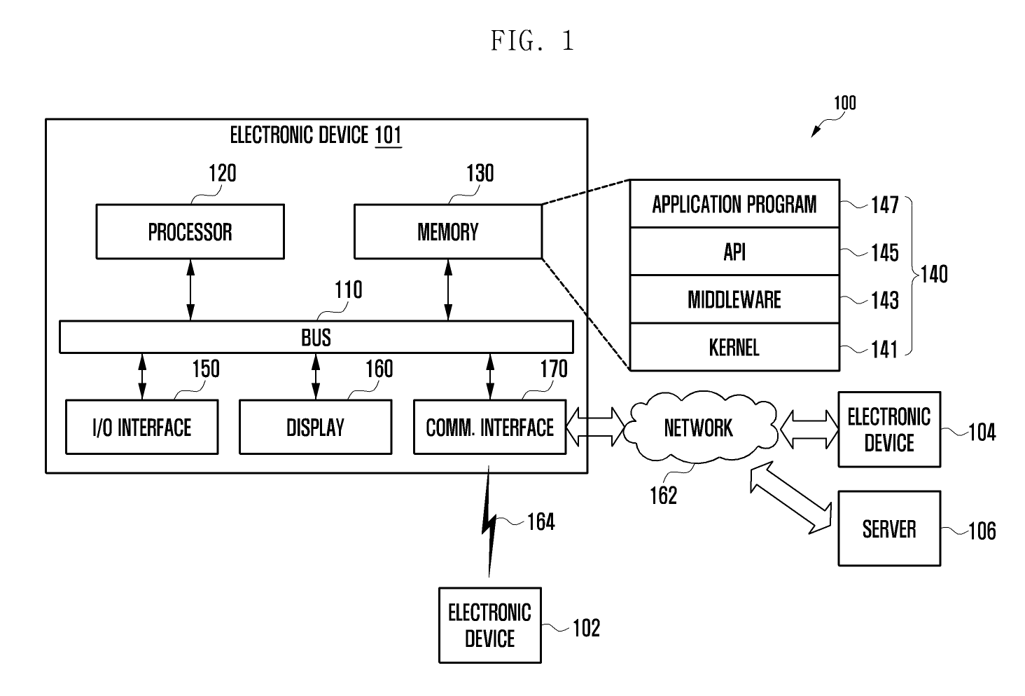

FIG. 1 is a diagram illustrating a network environment 100 including an electronic device 101 according to various embodiments of the present disclosure.

Referring to FIG. 1, the electronic device 101, 102 or 104 may be connected with a server 106 through a network 162 or short range communication 164.

The electronic device 101 may include a bus 110, a processor 120, a memory 130, an input/output (I/O) interface 150, a display 160, and a communication interface 170. In a certain embodiment, the electronic device 101 may omit at least one of the above elements or further include any other element.

The bus 110 may be a circuit which interconnects the above elements 120 to 170 and delivers a communication (e.g., a control message and/or data) between the above elements.

The processor 120 may include at least one of a central processing unit (CPU), an application processor (AP), or a communication processor (CP). The processor 120 may execute an operation or data processing for control and/or communication of at least one of other elements.

The memory 130 may include volatile and/or non-volatile memory. The memory 130 may store instructions or data related to at least one element of the electronic device 101. According to an embodiment, the memory 130 may store software and/or programs 140.

The programs 140 may include, for example, a kernel 141, a middleware 143, an application programming interface (API) 145, and/or an application program (or application) 147. At least some of the kernel 141, the middleware 143, and the API 145 may be referred to as an operating system (OS).

The kernel 141 may control or manage system resources (e.g., the bus 110, the processor 120, the memory 130, etc.) used to execute operations or functions implemented in other programs (e.g., the middleware 143, the API 145, and the application program 147). Also, the kernel 141 may provide an interface capable of accessing individual elements of the electronic device 101 through the middleware 143, the API 145, or the application program 147, and thereby controlling or managing system resources.

The middleware 143 may perform a function of an intermediary so that the API 145 or the application program 147 communicates with the kernel 143 and thereby exchanges data. In addition, the middleware 143 may process one or more work requests, received from the application program 147, according to priorities. For example, the middleware 143 may assign, to the application program 147, a priority for using system resources (e.g., the bus 110, the processor 120, the memory 130, etc.) of the electronic device 101 and then process the one or more work requests.

The API 145 is an interface through which the application 147 controls a function provided by the kernel 141 or the middleware 143, and may include, for example, at least one interface or function (e.g., instructions) for file control, window control, image processing, character control, and/or the like.

The I/O interface 150 may transmit commands or data, inputted from a user or other external device, to other element(s) of the electronic device 101, or output commands or data, received from other element(s) of the electronic device 101, to a user or other external device.

The display 160 may include, for example, a liquid crystal display (LCD), a light-emitting diode (LED) display, an organic light-emitting diode (OLED) display, a micro-electro-mechanical systems (MEMS) display, or an electronic paper display. The display 160 may display, for example, various contents (e.g., text, image, video, icon, symbol, etc.) to a user. The display 160 may include a touch screen and may receive, for example, a touch, gesture, proximity, or hovering input using an electronic pen or a portion of the user's body.

The communication interface 170 may establish communication between the electronic device 101 and an external device (e.g., a first external electronic device 102, a second external electronic device 104, or a server 106). For example, the communication interface 170 may be connected to the network 162 via wireless or wired communication and communicate with an external device (e.g., the second external electronic device 104 or the server 106).

The wireless communication may include cellular communication using at least one of, for example, LTE, LTE Advance (LTE-A), code division multiple access (CDMA), wideband CDMA (WCDMA), universal mobile telecommunications system (UMTS), wireless broadband (WiBro), global system for mobile communications (GSM), and the like. According to an embodiment, the wireless communication may include at least one of, for example, wireless fidelity (WiFi), Bluetooth, Bluetooth low power (BLE), Zigbee, near field communication (NFC), magnetic secure transmission, radio frequency (RF), or body area network (BAN). According to an embodiment, the wireless communication may include GNSS. The GNSS may be, for example, global positioning system (GPS), global navigation satellite system (Glonass), Beidou navigation satellite system (Beidou), or Galileo, the European global satellite-based navigation system. Hereinafter, in this disclosure, “GPS” may be used interchangeably with “GNSS”. The wired communications may include at least one of, for example, a universal serial bus (USB), a high definition multimedia interface (HDMI), a recommended standard 232 (RS-232), a power line communication, or a plain old telephone service (POTS). The network 162 may include a telecommunications network, for example, at least one of a computer network (e.g., LAN or WAN), the Internet, or a telephone network.

Each of the first and second external electronic devices 102 and 104 may be similar to or different from the electronic device 101 in types. According to various embodiments, all or part of operations performed in the electronic device 101 may be performed in another electronic device or multiple electronic devices (e.g., the electronic devices 102 and 104 and the server 106). According to an embodiment, in case of having to perform a certain function or service automatically or on demand, the electronic device 101 may request any other electronic device (e.g., the electronic device 102 or 104 or the server 106) to perform at least part of the function or service rather than or in addition to autonomously performing the function or service. Then, the other electronic device (e.g., the electronic device 102 or 104 or the server 106) may perform the requested function or service and return a result to the electronic device 101. The electronic device 101 may provide the requested function or service by using or further processing the received result. For this, cloud computing technique, distributed computing technique, or client-server computing technique may be utilized for example.

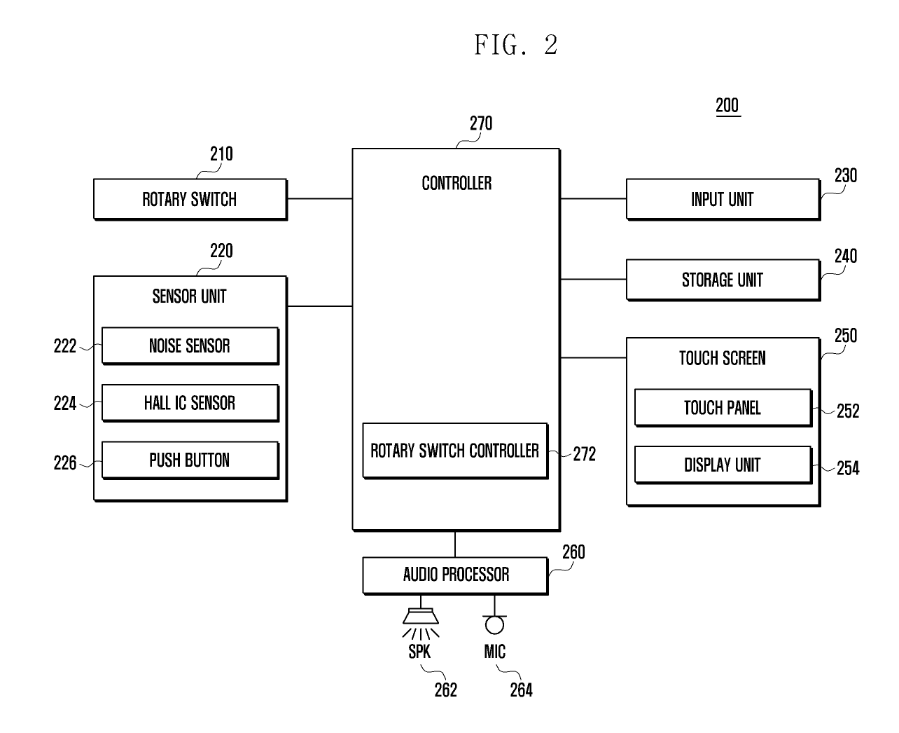

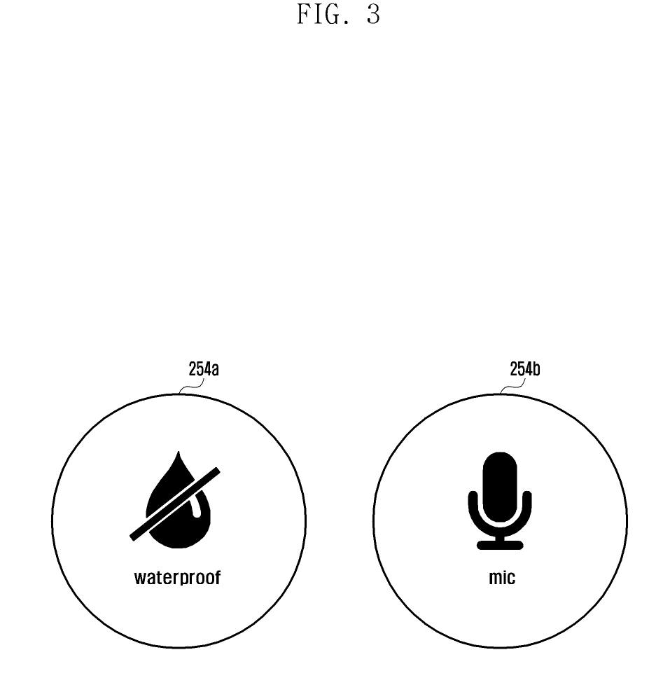

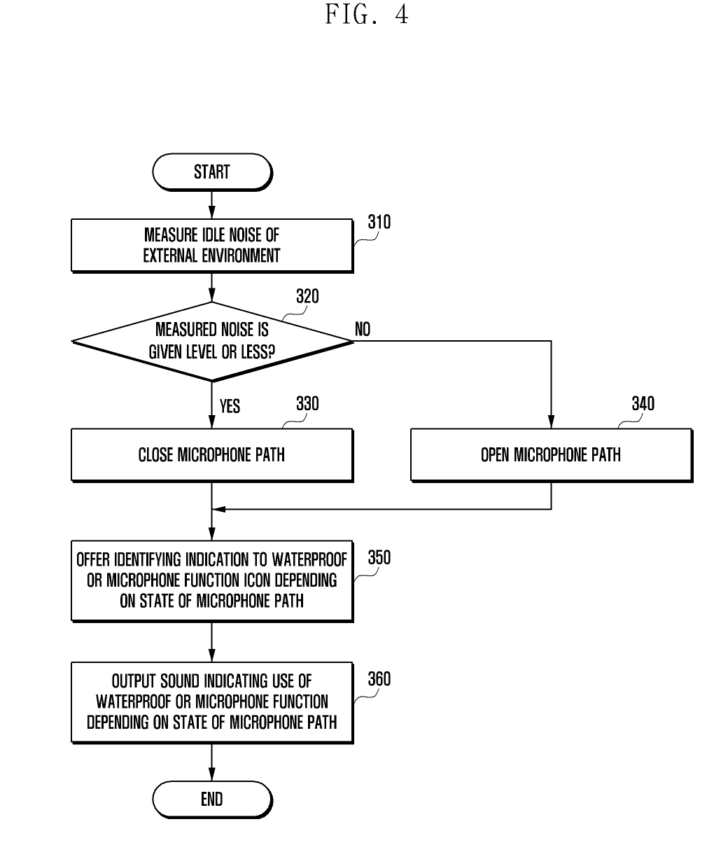

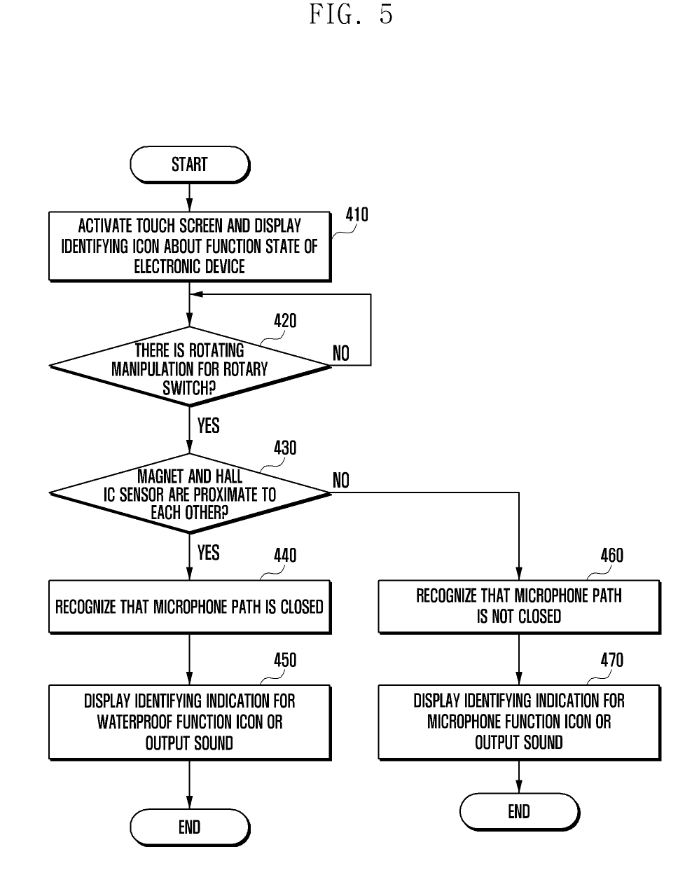

FIG. 2 is a block diagram illustrating a configuration of an electronic device 200 having a rotary switch 210 according to an embodiment of the present disclosure, and FIG. 3 is a diagram illustrating an example of a waterproof function icon 254a or a microphone function icon 254b displayed on a display unit 254 according to an embodiment of the present disclosure.

As shown in FIG. 2, the electronic device 200 according to an embodiment of the present disclosure may include a rotary switch 210, a sensor unit 220, an input unit 230, a storage unit 240, a touch screen 250, an audio processor 260, and a controller 270.

The rotary switch 210 may be a rotatable switching element configured to close or open a microphone path 1000 provided in the electronic device 200, as shown in FIG. 6, through a blocking member 2111 or a microphone hole 2110 by a rotating manipulation of the user. The electronic device 200 may selectively perform a waterproof function or a microphone function as the microphone path 1000 is closed or opened. Although the rotary switch 210 is illustrated as a means for closing or opening the microphone path 1000 of the electronic device 200, any other switching element capable of closing or opening the microphone path 1000 may be used alternatively.

The sensor unit 220 may detect whether the electronic device 200 performs a waterproof function or a microphone function. For example, the sensor unit 220 may detect whether the microphone path 1000 is closed through the blocking member 2111 or opened through the microphone hole 2110 in response to a rotation operation of the rotary switch 210.

The sensor unit 220 may include at least one of a noise sensor 222, a Hall IC sensor 224, and a push button 226.

When the external noise transmitted through the microphone path 1000 of the electronic device 200 drops to a certain level, e.g., approximately 20 db, or less, the noise sensor 222 may recognize that the microphone path 1000 is closed by the blocking member 2111.

The Hall IC sensor 224 may detect whether the microphone path 1000 is closed or opened, depending on the proximity or not of a magnet 214 (see FIG. 6) mounted on the end of the rotary switch 210. The Hall IC sensor 224 may use a Hall element for outputting, as a voltage value, the strength of a magnetic field which varies depending on the degree of the proximity of the magnet 214.

The push button 226 may detect the microphone path 1000 being closed when the push button 226 is pushed by the rotation of a rotor 213 integrated with the end of the rotary switch 210, and may detect the microphone path 1000 being opened when the push of the push button 226 is released. The above-described configuration of the magnet 214, the Hall IC sensor 224, and the push button 226 will be described in detail below with reference to FIGS. 6 and 9.

Although the sensor unit 220 is described as including any one of the noise sensor 222, the Hall IC sensor 224, and the push button 226, any other sensor capable of detecting, in response to a rotation operation of the rotary switch 210, whether the electronic device 200 is performing the waterproof function or the microphone function may be also used. For example, a proximity sensor, a touch sensor, a photo sensor, a pressure sensor, an optical sensor, a motion recognition sensor, an infrared sensor, a gravity sensor, a GBR (Green Blue Red) sensor, and/or the like may be possible.

The input unit 230 may receive a user's input for controlling the electronic device 200, generate a corresponding input signal, and deliver the input signal to the controller 270. The input unit 230 may be composed of a keypad having alphanumeric keys and navigation keys, and may include at least one function key on sides of the electronic device 200.

The storage unit 240 may perform a function of storing a program for processing and controlling of the controller 270, an operating system (OS), and input/output data. The storage unit 240 may store a program for controlling the overall operation of the electronic device 200.

In an embodiment of this disclosure, the storage unit 240 may store a particular program for automatically rotating the rotary switch 210 when the user selects the waterproof function icon 254a or the microphone function icon 254b, as shown in FIG. 3, displayed on the display unit 254 of the touch screen 250.

The touch screen 250 may perform an input function and a display function. For this, the touch screen 250 may include a touch panel 252 and the display unit 254. The touch panel 252 may be formed of a touch sensor of a capacitive overlay type, a resistive overlay type, or an infrared beam type, or may be formed of a pressure sensor. In addition to the above type sensors, any type of sensor capable of detecting contact or pressure of an object may be used for the touch panel 252 in various embodiments of this disclosure.

The touch panel 252 may sense a user's touch input. For example, when a user's finger, a stylus, or the like, which is a touch input tool, touches or approaches, the touch panel may generate a touch event and deliver the generated touch event to the controller 270. In detail, the touch panel 252 may recognize the occurrence of a touch event through a change in a physical quantity (e.g., capacitance, resistance, etc.) according to the touch or proximity of the touch input tool. The touch panel 252 may further include an electromagnetic induction type touch panel for recognizing an electronic pen of electromagnetic induction type.

The display unit 254 visually provides, to the user, a menu of the electronic device 200, input data, function setting information, and any other kind of information. In addition, the display unit 254 may inform the user about the operation state of the electronic device 200 through an icon as shown in FIG. 3. The display unit 254 may be formed of a liquid crystal display (LCD), an organic light emitting diode (OLED), an active matrix organic light emitting diode (AMOLED), a flexible display, a transparent display, or the like.

In an embodiment of this disclosure, when the waterproof function icon 254a or the microphone function icon 254b, displayed on the display unit 254 as shown in FIG. 3, is touched by the user, the touch panel 252 may allow the controller 270 to perform the selected function.

In addition, when the waterproof function or the microphone function of the electronic device 200 is performed in response to the rotation operation of the rotary switch 210, the display unit 254 may offer an identifying indication such as flashing, illumination, or particular colors to indicate an operating state of the waterproof function icon 254a or the microphone function icon 254b.

Although the electronic device 200 according to an embodiment of this disclosure is described as including the above-described touch screen 250, the electronic device is not limited thereto. In another embodiment, the electronic device 200 may include the display unit 254 only rather than the touch screen 250, and the function of the touch panel 252 may be performed by the sensor unit 220 or the input unit 230.

The audio processor 260 may be connected to a speaker (SPK) 262 for outputting an audio signal of a received call, an audio signal contained in a received message, an audio signal upon playback of an audio file stored in the storage unit 240, etc., and at least one microphone (MIC) 264 for collecting a user's voice, an ambient noise, and any other audio signal.

In an embodiment of this disclosure, when the waterproof function or the microphone function of the electronic device 200 is performed in response to the rotation operation of the rotary switch 210, the speaker 262 may provide sound associated with an operating state of a corresponding function to the user. For example, when the electronic device 200 performs the waterproof function, namely, when the microphone path 1000 is closed, the speaker 262 may output sound indicating a waterproof mode. When the electronic device 200 performs the microphone function, namely, when the microphone path 1000 is opened, the speaker 262 may output sound indicating a microphone mode.

In an embodiment of this disclosure, the microphone 264 is coupled to the noise sensor 222 described above and may assist the noise sensor 222 to measure an external sound, i.e., an ambient noise, through the microphone path 1000. The microphone 264 and the microphone path 1000 may be plural. For example, when one of the plurality of microphones 264 is in a call state, the audio processor 260 may allow the measurement of an external sound through any other microphone.

The controller 270 may control the overall operations and signal flows of respective elements of the electronic device 200, namely, the rotary switch 210, the sensor unit 220, the input unit 230, the storage unit 240, the touch screen 250, and the audio processor 260. For example, the controller 270 may be formed of a processor, a central processing unit (CPU), an application processor, a communication processor, and/or the like. The controller 270 may be formed of a single core processor or a multi-core processor. In addition, the controller 270 may include a plurality of processors.

In an embodiment of this disclosure, the controller 270 may include a rotary switch controller 272. When the user selects the waterproof function icon 254a or the microphone function icon 254b displayed on the display unit 254 of the touch screen 250, the rotary switch controller 272 may automatically rotate the rotary switch 210 to close or open the microphone path 1000.

In this embodiment, the rotary switch controller 272 is provided separately to control the rotary switch 210 in response to the selection of the waterproof function icon 254a or the microphone function icon 254b and to enable the electronic device 200 to perform the waterproof function or the microphone function. Alternatively, without the rotary switch controller 272 provided separately, the controller 270 may control the rotary switch 210 to select the waterproof function or the microphone function of the electronic device 200.

Hereinafter, a method for controlling a function of the electronic device 200 having the rotary switch 210 according to various embodiments will be described.

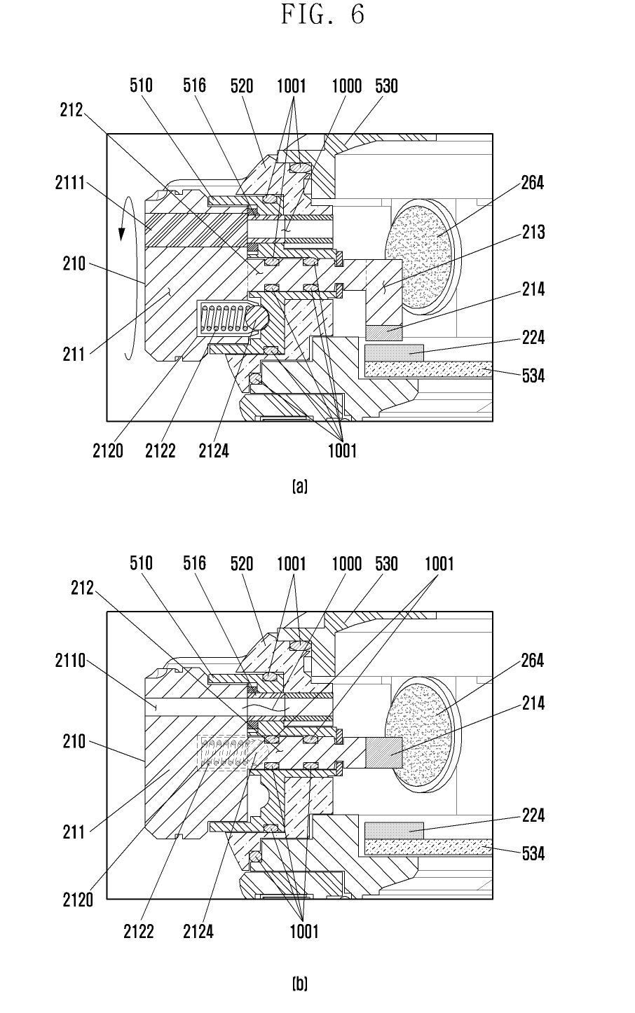

FIG. 4 is a flow diagram illustrating a method for controlling a function of an electronic device 200 having a rotary switch 210 through noise measurement of an external environment according to various embodiments of the present disclosure.

First, at operation 310, the controller 270 may measure an idle noise of an external environment delivered through the microphone path 1000 of the electronic device 200 by using the microphone 264 or the sensor unit 220. In an embodiment, the controller 270 may measure the ambient noise external to the electronic device 200 through the noise sensor 222 which may be coupled to the microphone 264.

Although it is described in an embodiment of this disclosure that the idle noise of the external environment is measured through the noise sensor 222, it is also possible to measure the idle noise of the external environment through the microphone 264.

Next, at operation 320, the controller 270 may determine whether the idle noise measured at operation 310 is a predetermined level, e.g., approximately 20 db, or less.

Then, if it is determined at operation 320 that the measured idle noise is equal to or smaller than the predetermined level, the controller 270 may recognize at operation 330 that the microphone path 1000 of the electronic device 200 is closed.

On the other hand, if it is determined at operation 320 that the measured idle noise is greater than the predetermined level, the controller 270 may recognize at operation 340 that the microphone path 1000 of the electronic device 200 is opened.

Thereafter, depending on the close or open state of the microphone path, the controller 270 may control at operation 350 the display unit 254 to offer an identifying indication such as flashing, illumination, or particular colors to indicate an operating state of the waterproof function icon 254a or the microphone function icon 254b as shown in FIG. 3.

At the same time, depending on the close or open state of the microphone path 1000, the controller 270 may control at operation 360 the speaker 262 to output sound to indicate the use of the waterproof function or the microphone function of the electronic device 200.

Therefore, the electronic device 200 according to various embodiments of this disclosure may indicate whether the electronic device 200 is in a waterproof mode or in a microphone mode, through icons and/or sound via the touch screen 250 or the microphone 264, so that the user can easily select a desired function through the waterproof function icon 254a or the microphone function icon 254b.

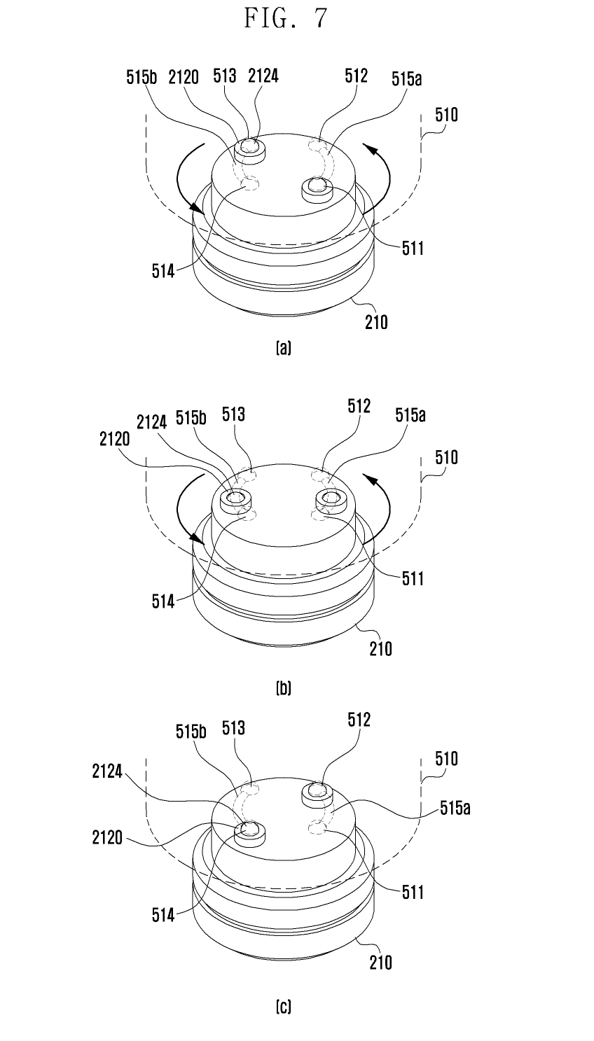

FIG. 5 is a flow diagram illustrating a method for controlling a function of an electronic device 200 having a rotary switch 210 through a magnet 214 and a Hall IC sensor 224 according to various embodiments of the present disclosure.

First, at operation 410, when the touch screen 250 is activated in response to a user's touch, the controller 270 may control the display unit 254 to display an operating state of the waterproof function or the microphone function of the electronic device 200. That is, depending on the close or open state of the microphone path 1000, the controller 270 may control the display unit 254 to offer an identifying indication such as flashing, illumination, or particular colors to indicate an operating state of the waterproof function icon 254a or the microphone function icon 254b as shown in FIG. 3.

Next, at operation 420, the controller 270 may determine whether there is a user's manipulation for rotating the rotatable element such as the rotary switch 210.

If there is no rotating manipulation for the rotary switch 210 at operation 420, the controller 270 may wait until there is a rotating manipulation.

On the other hand, if there is a user's rotating manipulation for the rotary switch 210 at operation 420, the controller 270 may determine at operation 430 whether the magnet 214 mounted on the rotor 213 of the rotary switch 210 and the Hall IC sensor 224 mounted on the PCB substrate 534 in the electronic device 200 are proximate to each other within a certain distance, e.g., about 0.01 mm to 0.02 mm.

If it is determined at operation 430 that the magnet 214 mounted on the rotor 213 and the Hall IC sensor 224 are proximate to each other within a certain distance, the controller 270 may recognize at operation 440 that the microphone path 1000 of the electronic device 200 is closed.

Next, at operation 450, the controller 270 may control the display unit 254 to offer an identifying indication such as flashing, illumination, or particular colors to the waterproof function icon 254a as shown in FIG. 3 or control the speaker 262 to output sound of indicating that the electronic device 200 is using the waterproof function.

On the other hand, if it is determined at operation 430 that the magnet 214 mounted on the rotor 213 and the Hall IC sensor 224 are not proximate to each other within a certain distance, the controller 270 may recognize at operation 460 that the microphone path 1000 of the electronic device 200 is not closed and is opened.

Thereafter, at operation 470, the controller 270 may control the display unit 254 to offer an identifying indication such as flashing, illumination, or particular colors to the microphone function icon 254b or control the speaker 262 to output sound of indicating that the electronic device 200 is using the microphone function.

Parts (a) and (b) of FIG. 6 are diagrams illustrating configurations for implementing the method, shown in FIG. 5, for controlling a function of an electronic device 200 through a magnet 214 and a Hall IC sensor 224. Specifically, part (a) of FIG. 6 shows a state where the electronic device 200 performs a waterproof function, and part (b) shows a state where the electronic device 200 performs a microphone function. Parts (a) to (c) of FIG. 7 are diagrams illustrating an operating relationship between a rotary switch 210 and a housing 510 thereof.

As shown in FIG. 6, the electronic device 200 according to various embodiments of this disclosure may includes a rotary switch 210, a rotary switch housing 510, an interface 520, and an electronic device case 530.

The rotary switch 210 is a switching means for closing or opening the microphone path 1000 provided in the electronic device 200 in response to a user's rotating manipulation. The rotary switch 210 may include a rotary lever 211, a rotary shaft 212, and a rotor 213 which are integrally connected to each other.

The rotary switch 210 may have a circular rod shape having at least one step and a decreasing width from one end to the other end. The rotary lever 211 is rotatable in a forward direction (clockwise direction) or a reverse direction (counterclockwise direction) by a user's manipulation and may include, at one portion thereof, a microphone hole 2110 communicating with the microphone path 1000 to receive an external sound, and, at other portion thereof, a blocking member 2111 for closing the microphone path 1000 to block an external sound and water. The rotary lever 211 may have at least one click member 2120 which is detachably engaged with a plurality of concave places 511, 512, 513, and 514 formed in the rotary switch housing 510 as shown in FIG. 7 and provides a sense of click. The click member 2120 may have a tubular shape in which the outer peripheral surface on the inlet side is inclined inward. The click member 2120 may include an extendable and retractable spring 2122 whose one end is fixed to the inner surface of the click member 2120 and the other end is fixed to a ball 2124. The rotor shaft 212 is integrally connected, at one end thereof, to an inner end of the rotary lever 211 and can rotate in conjunction with forward or reverse rotation of the rotary lever 211. A plurality of insertion grooves are formed on the outer circumferential surface of the rotor shaft 212. A packing member 1001 having a waterproof function may be embedded in each insertion groove. The rotor 213 is integrally connected to the other end of the rotor shaft 212 at a certain angle, for example, about 90 degrees, and rotates together with the rotation of the rotary lever 211. The magnet 214 is mounted at a distal end of the rotor 213 to provide a magnetic field indicative of proximity to the Hall IC sensor 224.

The rotary switch housing 510 may have a shape corresponding to the outer diameter of the rotary switch 210 having a circular rod shape having at least one step and a decreasing width from one end to the other end. The rotary switch housing 510 may cover up to a portion of the rotor shaft 212. A plurality of insertion grooves are formed on the outer circumferential surface of the rotary switch housing 510, and the packing member 1001 having a waterproof function may be embedded in each insertion groove. A cylindrical waterproof member 516 may be provided at a certain position of the rotary switch housing 510. The waterproof member 516 may communicate with the microphone path 1000. The waterproof member 516 may be disposed at a corresponding position of the microphone hole 2110 or the blocking member 2111 which is moved together with the rotation of the rotary lever 211 of the rotary switch 210. That is, when the waterproof member 516 is positioned in line with the microphone path 1000 and the microphone hole 2110, the waterproof member 516 functions as the microphone path 1000 as shown in part (b) of FIG. 6. Also, when the waterproof member 516 is positioned in the line with the microphone path 1000 and the blocking member 2111, the waterproof member 516 performs a waterproof function as shown in part (a) of FIG. 6. Each of the waterproof member 516 and the blocking member 2111 is formed of any one of Gore-Tex, silicone, rubber, and urethane, and may be disposed in close contact with each other when performing a waterproof function. Also, the packing member 1001 may be formed of any one of Gore-Tex, silicone, rubber, and urethane. Each of the waterproof member 516, the blocking member 2111, and the packing member 1001 may be made of any other material allowing a waterproof function.

As shown in FIG. 7, the inner surface of the rotary switch housing 510 may be provided with, for example, a first concave place 511, a second concave place 512, a third concave place 513, and a fourth concave place 514. A first arched guide groove 515a may be formed between the first concave place 511 and the second concave place 512, and also a second arched guide groove 515b may be formed between the third concave place 513 and the fourth concave place 514. At this time, the first to fourth concave places 511 to 514 may be formed deeper than the first and second guide grooves 515a and 515b to provide a sense of click. For example, as shown in part (a) of FIG. 7, the user may rotate the rotary lever 211 of the rotary switch 210 in the reverse direction (counterclockwise direction) in a state where the ball 2124 mounted at the distal end of the spring 2122 provided on the click member 2120 is positioned in each of the first and third concave places 511 and 513. Then, as shown in part (b) of FIG. 7, the ball 2124 moves along each of the first and second arched guide grooves 515a and 515b being formed higher than the first and third concave places 511 and 513. Finally, as shown in part (c) of FIG. 7, the ball 2124 is positioned in and engaged with each of the second and fourth concave places 512 and 514 while producing a click sound, thereby providing a sense of click according to the function selection to the user.

The interface 520 may be an intermediate medium capable of connecting the rotary switch housing 510 and the electronic device case 530. A plurality of insertion grooves are formed on the inner circumferential surface and/or the outer circumferential surface of the interface 520, and the packing member 1001 having a waterproof function may be embedded in each insertion groove. Also, an insertion groove is formed at a step edge of the interface 520 facing the electronic device case 530, and the packing member 1001 having a waterproof function may be embedded in this insertion groove. The microphone path 1000 may be formed at a certain position of the interface 520, for example, at a position corresponding to the waterproof member 516, so as to receive an external sound.

The electronic device case 530 may form an outer surface of the electronic device 200. The microphone 264 may be provided at a certain position inside the electronic device case 530. A PCB substrate 534 on which various components constituting the electronic device 200 are mounted may be disposed in the electronic device case 530. The Hall IC sensor 224 may be disposed on a part of the PCB substrate 534 to detect the proximity of the magnet 214 according to the rotation of the rotary switch 200. That is, the Hall IC sensor 224 is disposed on the PCB substrate 534 to face the magnet 214 and detect the magnetic field of the magnet 214.

Therefore, as described in FIGS. 5 to 7, the electronic device 200 according to various embodiments of this disclosure may indicate whether the electronic device 200 is in a waterproof mode or in a microphone mode, through icons and/or sound, depending on whether the magnet 214 and the Hall IC sensor 224 are proximate to each other, so that the user can easily select a desired function through the waterproof function icon 254a or the microphone function icon 254b.

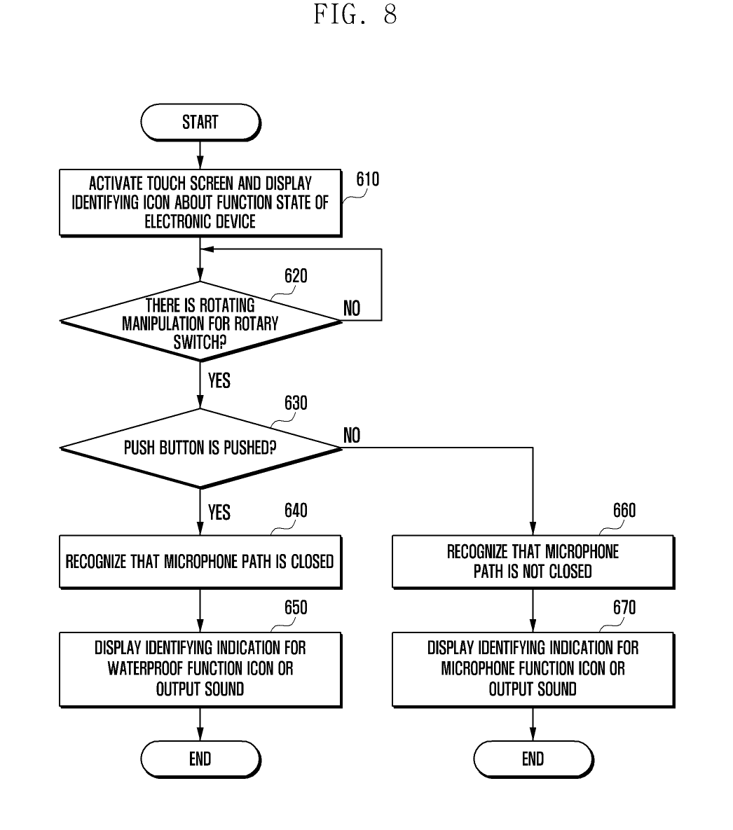

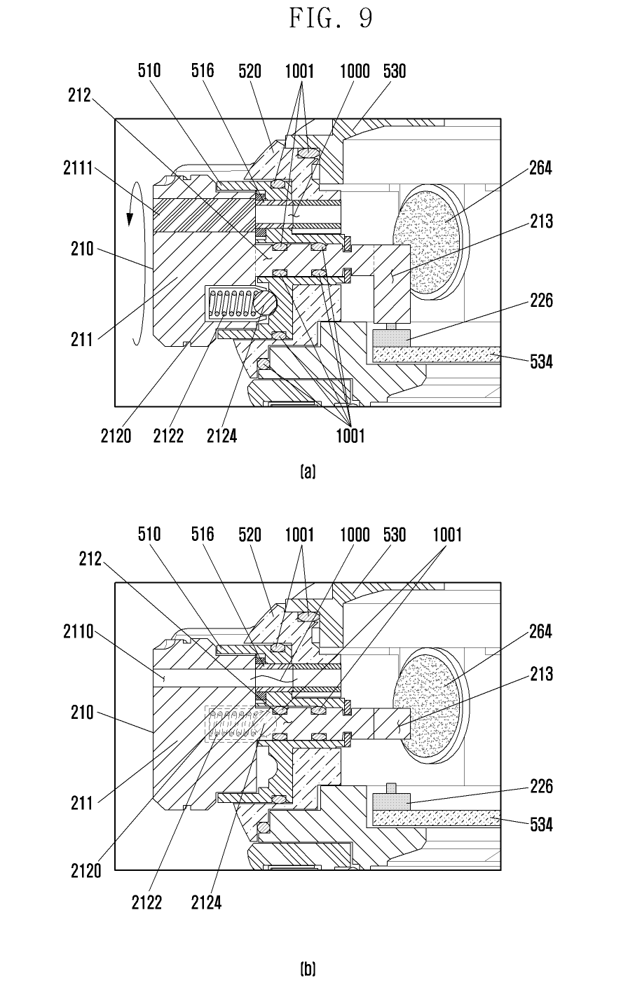

FIG. 8 is a flow diagram illustrating a method for controlling a function of an electronic device 200 having a rotary switch 210 through a push button 226 according to various embodiments of the present disclosure.

First, at operation 610, when the touch screen 250 is activated in response to a user's touch, the controller 270 may control the display unit 254 to display a current functional state of the electronic device 200. That is, the controller 270 may control the display unit 254 to offer an identifying indication such as flashing, illumination, or particular colors to the waterproof function icon 254a or the microphone function icon 254b as shown in FIG. 3, depending on the close or open state of the microphone path 1000.

Next, at operation 620, the controller 270 may determine whether there is a user's manipulation for rotating the rotary switch 210.

If there is no rotating manipulation for the rotary switch 210 at operation 620, the controller 270 may wait until there is a rotating manipulation.

On the other hand, if there is a user's rotating manipulation for the rotary switch 210 at operation 620, the controller 270 may determine at operation 630 whether the push button 226 mounted on the PCB substrate 534 in the electronic device 200 is pushed by the rotor 213 of the rotary switch 210.

If it is determined at operation 630 that the push button 226 is pushed by the rotor 213 of the rotary switch 210, the controller 270 may recognize at operation 640 that the microphone path 1000 of the electronic device 200 is closed.

Next, at operation 650, the controller 270 may control the display unit 254 to offer an identifying indication such as flashing, illumination, or particular colors to the waterproof function icon 254a as shown in FIG. 3 or control the speaker 262 to output sound of indicating that the electronic device 200 is using the waterproof function.

On the other hand, if it is determined at operation 630 that the push button 226 is not pushed by the rotor 213 of the rotary switch 210, the controller 270 may recognize at operation 660 that the microphone path 1000 of the electronic device 200 is not closed.

Thereafter, at operation 670, the controller 270 may control the display unit 254 to offer an identifying indication such as flashing, illumination, or particular colors to the microphone function icon 254b or control the speaker 262 to output sound of indicating that the electronic device 200 is using the microphone function.

Parts (a) and (b) of FIG. 9 are diagrams illustrating configurations for implementing the method, shown in FIG. 8, for controlling a function of an electronic device through a push button. Specifically, part (a) of FIG. 9 shows a state where the electronic device 200 performs a waterproof function, and part (b) shows a state where the electronic device 200 performs a microphone function.

The same reference numerals are given to the same elements as those described with reference to FIG. 6, and a detailed description thereof will be omitted. Only different elements and operations will be described.

As shown in FIG. 9, the rotor 213 of the rotary switch 210 may push or release the push button 226 which may be disposed on a part of the PCB substrate 534. As shown in part (a) of FIG. 9, when the rotor 213 of the rotary switch 210 pushes the push button 226, the blocking member 2111 blocks the microphone path 1000 and thus the waterproof function is performed. On the other hand, as shown in part (b) of FIG. 9, when the rotor 213 of the rotary switch 210 is rotated in the reverse direction (counterclockwise direction) by a user's manipulation and thereby the push of the push button 226 is released, the microphone hole 2110 communicates with the microphone path 1000 and thus the microphone function is performed.

Therefore, as described in FIGS. 8 and 9, the electronic device 200 according to various embodiments of this disclosure may indicate whether the electronic device 200 is in a waterproof mode or in a microphone mode, through icons and/or sound, depending on whether the rotor 213 of the rotary switch 210 pushes the push button 226.

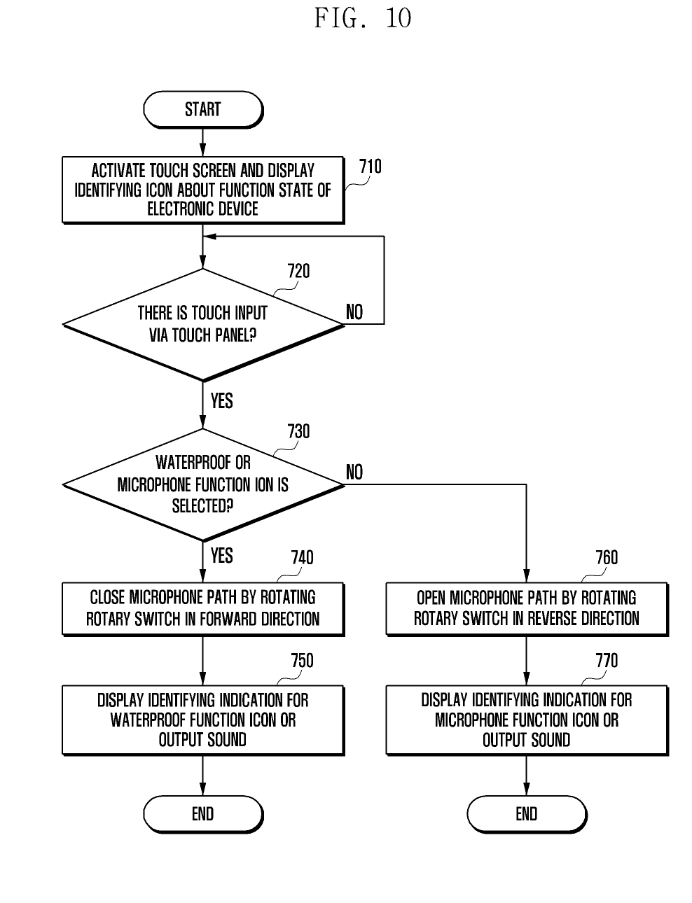

FIG. 10 is a flow diagram illustrating a method for controlling a function of an electronic device 200 having a rotary switch 210 through a touch screen 250 according to various embodiments of the present disclosure.

First, at operation 710, when the touch screen 250 is activated in response to a user's touch, the controller 270 may control the display unit 254 to display a current functional state of the electronic device 200. That is, the controller 270 may control the display unit 254 to offer an identifying indication such as flashing, illumination, or particular colors to the waterproof function icon 254a or the microphone function icon 254b as shown in FIG. 3, depending on the close or open state of the microphone path 1000.

Next, at operation 720, the controller 270 may determine whether there is a user's touch input for selecting a function through the touch panel 252. If there is no touch input on the touch panel 252 at operation 720, the controller 270 may wait until there is a rotating manipulation.

If there is a user's touch input through the touch panel 252 at operation 720, the controller 270 may determine at operation 730 whether the user selects the waterproof function icon 254a or the microphone function icon 254b.

If the user selects the waterproof function icon 254a through the touch panel 252, the controller 270 may rotate at operation 740 the rotary switch 210 in the forward direction (clockwise direction) to close the microphone path 1000 through the blocking member 2111. Although it is described that the controller 270 rotates the rotary switch 210 at operation 740, the rotary switch 210 may be rotated through the rotary switch controller 272 mounted separately to the rotary switch 210.

Next, at operation 750, the controller 270 may control the display unit 254 to offer an identifying indication such as flashing, illumination, or particular colors to the waterproof function icon 254a as shown in FIG. 3 or control the speaker 262 to output sound of indicating that the electronic device 200 is using the waterproof function.

On the other hand, if it is determined at operation 730 that the user selects the microphone function icon 254b through the touch panel 252, the controller 270 may rotate at operation 760 the rotary switch 210 in the reverse direction (counterclockwise direction) to open the microphone path 1000 by aligning the microphone hole 2110 and the microphone path 1000 in a line.

Thereafter, at operation 770, the controller 270 may control the display unit 254 to offer an identifying indication such as flashing, illumination, or particular colors to the microphone function icon 254b or control the speaker 262 to output sound of indicating that the electronic device 200 is using the microphone function.

Therefore, as described in FIG. 10, the electronic device 200 according to various embodiments of this disclosure may allow the user to easily select the waterproof function or the microphone function by rotating the rotary switch 210 through the controller 270 when the waterproof function icon 254a or the microphone function icon 254b displayed on the touch screen 250 is touched.

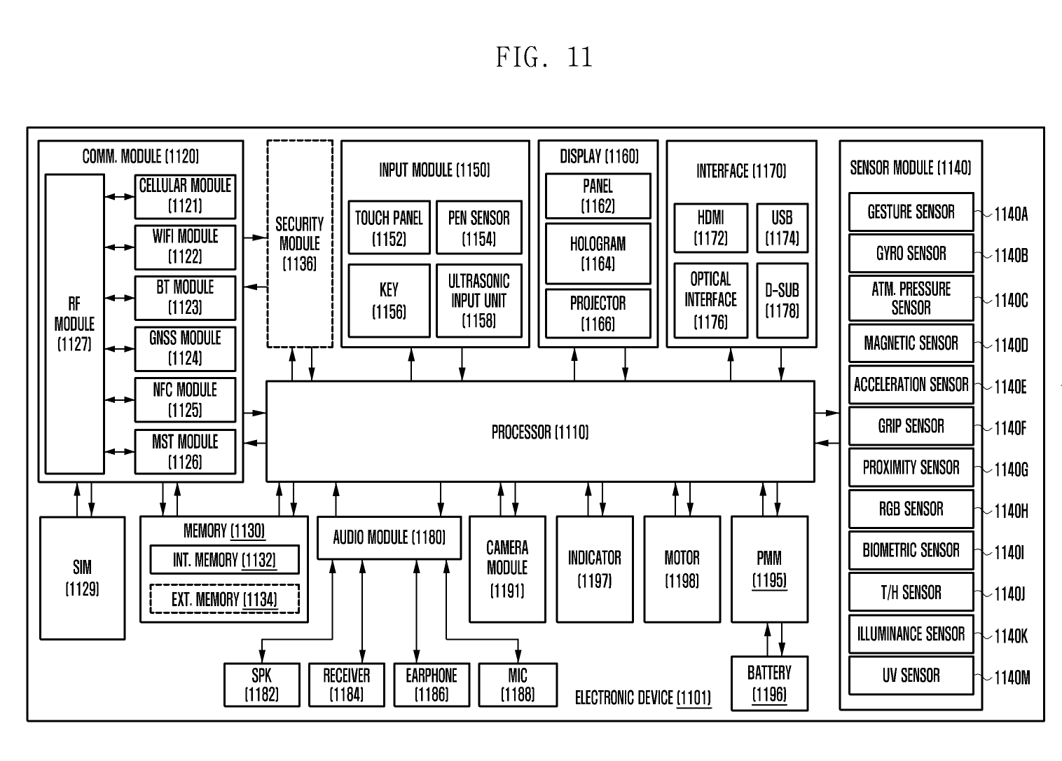

FIG. 11 is a block diagram of an electronic device 1101 according to various embodiments of the present disclosure.

The electronic device 1101 may include all or part of the electronic device 101 shown in FIG. 1. The electronic device 1101 may include one or more processor (e.g., AP) 1110, a communication module 1120, a subscriber identification module (SIM) 1129, a memory 1130, a security module 1136, a sensor module 1140, an input module 1150, a display module 1160, an interface 1170, an audio module 1180, a camera module 1191, a power management module 1195, a battery 1196, an indicator 1197, and a motor 1198.

The processor 1110 may execute an operating system (OS) or an application program, control multiple hardware or software components connected to the processor 1110, and perform processing and operations on various data. The processor 1110 may be implemented by, for example, a system on chip (SoC). According to an embodiment, the processor 1110 may further include a graphic processing unit (GPU) and/or an image signal processor. The processor 1110 may include at least some of elements shown in FIG. 11 (e.g., a cellular module 1121). The processor 1110 may load and process instructions or data received from at least one of the other elements (e.g., non-volatile memory) into volatile memory and then store the resulting data in non-volatile memory.

The communication module 1120 may be, for example, the communication module 170 shown in FIG. 1. The communication module 1120 may include, for example, a cellular module 1121, a Wi-Fi module 1122, a Bluetooth (BT) module 1123, a GNSS module 1124 (e.g., a GPS module, a Glonass module, a Beidou module, or a Galileo module), an NFC module 1125, an MST module 1126, and a radio frequency (RF) module 1127.

The cellular module 1121 may provide a voice call, a video call, a messaging service, or an Internet service, for example, through a communication network. According to an embodiment, the cellular module 1121 may utilize the subscriber identity module (e.g., a SIM card) 1129 to perform the identification and authentication of the electronic device 1101 in the communication network. According to an embodiment, the cellular module 1121 may perform at least some of functions that the processor 1110 may provide. According to an embodiment, the cellular module 1121 may include a communications processor (CP).

According to a certain embodiment, at least some (e.g., two or more) of the cellular module 1121, the WiFi module 1122, the Bluetooth module 1123, the GNSS module 1124, or the NFC module 1125 may be included in an integrated chip (IC) or an IC package. The RF module 1127 may, for example, transmit and receive communication signals (e.g., RF signals).

The RF module 1127 may include, for example, a transceiver, a power amplifier module (PAM), a frequency filter, a low noise amplifier (LNA), or an antenna. According to another embodiment, at least one of the cellular module 1121, the WiFi module 1122, the Bluetooth module 1123, the GNSS module 1124, or the NFC module 1125 may transmit and receive RF signals through separate RF modules.

The SIM 1129 may include, for example, a card having SIM or an embedded SIM, and may include unique identification information (e.g., an integrated circuit card identifier (ICCID), or an international mobile subscriber identity (IMSI)).

The memory 1130 (e.g., the memory 130 shown in FIG. 1) may include an internal memory 1132 and an external memory 1134. The internal memory 1132 may include, for example, at least one of a volatile memory (e.g., a DRAM, an SRAM, or SDRAM), and a non-volatile memory (e.g., a one time programmable ROM (OTPROM), a PROM, an EPROM, an EEPROM, a mask ROM, a flash ROM, a flash memory, a hard drive, or a solid state drive (SSD)).

The external memory 1134 may include a flash drive, for example, a compact flash (CF), a secure digital (SD), a micro-SD, a mini-SD, an extreme Digital (xD), or a memory stick. The external memory 1134 may be functionally or physically connected to the electronic device 1101 through various interfaces.

The security module 1136 is a module including a storage space having a relatively higher security level than the memory 1130, and may be a circuit that ensures secure data storage and a protected execution environment. The security module 1136 may be implemented as a separate circuit and may include a separate processor. The security module 1136 may exist in a removable smart chip or a secure digital (SD) card, for example, or may include an embedded secure element (eSE) embedded in a fixed chip of the electronic device 1101. In addition, the security module 1136 may be operated with an operating system other than the operating system (OS) of the electronic device 1101. For example, it may be operated on a Java card open platform (JCOP) operating system.

The sensor module 1140 may, for example, measure a physical quantity or sense an operating state of the electronic device 1101 and convert the measured or sensed information into an electrical signal. The sensor module 1140 may include, for example, at least one of a gesture sensor 1140A, a gyro sensor 1140B, an atmospheric pressure sensor 1140C, a magnetic sensor 1140D, an acceleration sensor 1140E, a grip sensor 1140F, a proximity sensor 1140G, a color sensor 1140H (e.g., RGB (red, green and blue) sensor), a biometric sensor 1140I, a temperature/humidity sensor 1140J, an illuminance sensor 1140K, and a ultra violet (UV) sensor 1140M. Additionally or alternatively, the sensor module 1140 may include, for example, an e-nose sensor, an electromyography (EMG) sensor, an electroencephalogram (EEG) sensor, an electroardiogram (ECG) sensor, an infrared (IR) sensor, an iris sensor, and/or a fingerprint sensor. The sensor module 1140 may further include a control circuit for controlling one or more sensors included therein. In a certain embodiment, the electronic device 1101 further includes a processor configured to control the sensor module 1140, either as part of the processor 1110 or separately, to control the sensor module 1140 while the processor 1110 is in a sleep state.

The input module 1150 may include a touch panel 1152, a (digital) pen sensor 1154, keys 1156, and an ultrasonic input unit 1158. The touch panel 1152 may use at least one of, for example, a capacitive scheme, a resistive scheme, an infrared scheme, and an acoustic wave scheme. In addition, the touch panel 1152 may further include a control circuit. The touch panel 1152 may further include a tactile layer to provide a tactile response to the user. The (digital) pen sensor 1154 may be a part of the touch panel or include a separate sheet for recognition. For example, the keys 1156 may include a physical key, an optical key, or a key pad. The ultrasonic input unit 1158 may sense the ultrasonic wave generated from an input tool through the microphone (e.g., the microphone 264) and identify data corresponding to the sensed ultrasonic wave.

The display module 1160 (e.g., the display unit 160) may include a panel 1162, or a hologram 1164, a projector 1166, and/or a control circuit for controlling them. The panel 1162 may be implemented so as to be, for example, flexible, transparent, or wearable. The panel 1162 may include the touch panel 1152 and one or more modules. The hologram 1164 may display a three-dimensional image in the air by using interference of light. The projector 1166 may display an image by projecting light onto a screen. The screen may be located, for example, inside or outside the electronic device 1101. The interface 1170 may include, for example, an HDMI 1172, a USB 1174, an optical interface 1176, or a D-sub (D-subminiature) 1178.

The interface 1170 may be included in the communication interface 170 shown in FIG. 1, for example. Additionally or alternatively, the interface 1170 may include, for example, a mobile high-definition link (MHL) interface, an SD card/MMC (multi-media card) interface, or an infrared data association (IrDA) based interface.

The audio module 1180 may convert, for example, sound into electric signals, and vice versa. At least some of components of the audio module 1180 may be included, for example, in the I/O interface 150 shown in FIG. 1. The audio module 1180 may process sound information inputted or outputted through, for example, a speaker 1182, a receiver 1184, an earphone 1186, or a microphone 1188.

The camera module 1191 is a device capable of capturing still images or video. According to an embodiment, the camera module 1191 may include one or more image sensors (e.g., front sensor or rear sensor), a lens, an image signal processor (ISP), or a flash (e.g., LED or xenon lamp).

The power management module 1195 may manage electrical power of the electronic device 1101. According to an embodiment, the power management module 1195 may include, for example, a power management integrated circuit (PMIC), a charger IC, or a battery fuel gauge. The PMIC may use wired and/or wireless charging scheme. The wireless charging scheme includes, for example, a magnetic resonance scheme, a magnetic induction scheme, or an electromagnetic wave scheme, and may further include an additional circuit for wireless charging, for example, a coil loop, a resonance circuit, or a rectifier. The battery gauge may measure, for example, a charge level, a voltage while charging, or a temperature of the battery 1196.

The battery 1196 may include, for example, a rechargeable battery and/or a solar cell.

The indicator 1197 may indicate one or more states (e.g., boot status, message status or charge status) of the electronic device 1101 or a portion thereof (e.g., the processor 1110).

The motor 1198 may convert electrical signal into mechanical vibration and produce a vibration, haptic effect, or the like. The electronic device 1101 may include a mobile TV supporting device (e.g., GPU) capable of processing media data conforming to standards such as digital multimedia broadcasting (DMB), digital video broadcasting (DVB), or mediaFlo™.

Each of the above-described elements may include one or more components, and the name of such an element may be varied depending on the type of electronic device. In various embodiments, the electronic device (e.g., 1101) may not include at least one of the above-described elements or further include additional elements. In addition, some of the elements may be combined into one entity, which may perform functions identical to those of the elements before the combination.

The term “module” used herein may refer to, for example, a unit including one of hardware, software, and firmware, or a combination thereof. The term module may be interchangeable with a term such as logic, a logical block, a component, or a circuit. The “module” may be a minimum unit of an integrated component or a part thereof or for performing one or more functions or a part thereof. The “module” may be mechanically or electronically implemented and may include at least one of an application-specific integrated circuit (ASIC) chip, a field-programmable gate arrays (FPGA), or a programmable-logic device for performing operations which has been known or are to be developed hereinafter.

According to various embodiments of the present disclosure, at least some of the devices (e.g., modules or functions thereof) or the method (e.g., operations) may be implemented as instructions stored in a non-transitory computer-readable storage medium (e.g., the memory 130) in a programming module form. When the instructions are executed by a processor (e.g., the processor 120), the processor may execute a function corresponding to the instructions.

The non-transitory computer-readable recording medium may include a hard disk, a floppy disk, a magnetic medium (e.g., a magnetic tape), an optical medium (e.g., CD-ROM, DVD), a magneto-optical medium (e.g., a floptical disk), an embedded memory, and the like. The instructions may include codes made by a compiler or executable in an interpreter. The module or program module according to various embodiments may include at least one or more of the above-described elements, some of them may be omitted, or other elements may be further included. Operations according to various embodiments performed by modules, program modules, or other components may be performed sequentially, in parallel, repetitively, or heuristically, or at least some operations may be performed in a different order, omitted, or need any other operation.

While the present disclosure has been shown and described with reference to various embodiments thereof, it will be understood by those skilled in the art that various changes in form and details may be made therein without departing from the subject matter and scope of the present disclosure as defined by the appended claims and their equivalents.

What is claimed is:

1. An electronic device comprising:
a switching element configured to close or open a microphone path so that a first function or a second function is performed;
a sensor unit configured to detecting whether the microphone path is closed or opened;
a touch screen configured to display whether the first function or the second function is performed; and
a controller configured to perform the first function or the second function.

2. The electronic device of claim 1, wherein the first function is a waterproof function of the electronic device and the second function is a microphone function.

3. The electronic device of claim 1, wherein the touch screen includes:
a touch panel configured to support the electronic device select the first function or the second function; and
a display unit configured to display whether the electronic device performs the first function or the second function.

4. The electronic device of claim 1, wherein the switching element includes a rotary switch configured to close or open the microphone path through a blocking member.

5. The electronic device of claim 1, wherein the sensor unit includes:
a noise sensor for measuring an external noise,
a Hall IC sensor for detecting whether a magnet equipped in the switching element is proximate or not, and
a push button pushed or released by the switching element.

6. The electronic device of claim 1, further comprising:
a speaker configured to output a sound indicating whether the electronic device performs the first function or the second function.

7-10. (canceled)

11. A method for controlling a function of an electronic device, the method comprising:
at a controller, displaying, through a display unit, a state of performing a first function or a second function by the electronic device;
at the controller, determining whether there is a rotation operation of a switching element;
at the controller, detecting a completion of the rotation operation of the switching element;
at the controller, when the completion of the rotation operation of the switching element is detected, recognizing that a microphone path of the electronic device is closed; and
at the controller, providing an identifying indication to a first function icon through a display unit.

12. The method of claim 11, wherein the first function is a waterproof function of the electronic device and the second function is a microphone function.

13. The method of claim 11, wherein the detecting a completion of the rotation operation of the switching element includes, at the controller, detecting whether a magnet mounted on the switching element and an Hall IC sensor in the electronic device are proximate to each other within a given distance.

14. The method of claim 11, wherein the detecting a completion of the rotation operation of the switching element includes, at the controller, detecting whether the switching element pushes a push button in the electronic device.

15. The method of claim 11, further comprising:
at the controller, when recognizing that the microphone path of the electronic device is closed, outputting, through a speaker, a sound indicating that the electronic device performs the first function.

16. The method of claim 11, further comprising:
at the controller, when the completion of the rotation operation of the switching element is not detected, recognizing that the microphone path of the electronic device is opened.

17. The method of claim 16, further comprising:
at the controller, when recognizing that the microphone path of the electronic device is opened, providing an identifying indication to a second function icon through the display unit or outputting, through a speaker, a sound indicating that the electronic device performs the second function.

18. A method for controlling a function of an electronic device, the method comprising:
at a controller, displaying, through a display unit, a state of performing a first function or a second function by the electronic device;
at the controller, determining whether there is a touch input through a touch panel;
at the controller, when there is the touch input, determining whether a first function icon or a second function icon is selected; and
at the controller, when there is a signal of selecting the first function icon, closing a microphone path through a blocking member by rotating a switching element in one direction.

19. The method of claim 18, wherein the first function is a waterproof function of the electronic device and the second function is a microphone function.

20. The method of claim 18, further comprising:
at the controller, when the microphone path is closed, providing an identifying indication to the first function icon through the display unit or outputting, through a speaker, a sound indicating that the first function is performed.

21. The method of claim 18, further comprising:
at the controller, when there is a signal of selecting the second function icon, opening the microphone path through a microphone hole by rotating the switching element in a reverse direction.

22. The method of claim 21, further comprising:
at the controller, when the microphone path is opened, providing an identifying indication to the second function icon through the display unit or outputting, through a speaker, a sound indicating that the second function is performed.

23-24. (canceled)
